(19) United States
(12) Patent Application Publication
(10) Pub. No.: US 2014/0246714 A1
(43) Pub. Date: Sep. 4, 2014

(54) IMAGE SENSOR HAVING THIN DARK SHIELD

(71) Applicant: DONGBU HITEK CO., LTD., Seoul (KR)

(72) Inventor: Chang Eun LEE, Seoul (KR)

(73) Assignee: DONGBU HITEK CO., LTD., Seoul (KR)

(21) Appl. No.: 13/803,122

(22) Filed: Mar. 14, 2013

(30) Foreign Application Priority Data
Mar. 4, 2013 (KR) 10-2013-0023046

(51) Int. Cl. H01L 27/146

(52) U.S. Cl. CPC H01L 27/14623; H01L 27/14683
USPC 257/294; 438/69

(57) ABSTRACT

An image sensor and method of manufacturing the same are provided. The image sensor can include a pixel array region having an active pixel area and a dark pixel area surrounding the active pixel area. A dark shield can be formed in the dark pixel area to inhibit light. Dark pixels can be provided under the dark shield. The dark shield can include a thin film including silicon chromium (SiCr).

### CROSS-REFERENCE TO RELATED APPLICATION

This application claims the benefit under 35 U.S.C. §119 of Korean Patent Application No. 10-2013-0023046, filed Mar. 4, 2013, which is hereby incorporated by reference in its entirety.

### BACKGROUND

Image sensors convert optical information into electrical signals. Among image sensors, a complimentary metal oxide semiconductor (CMOS) image sensor is a device that converts an optical image into an electrical signal by using a CMOS manufacturing technique and employs a switching type that sequentially detects outputs by using a MOS transistor for each pixel.

A CMOS image sensor has simpler driving methods and more various scanning methods than a charge coupled device (CCD) image sensor that is widely used as a related art image sensor. In addition, since analog and digital signal processing circuits are integrated into a single chip, product miniaturization may be possible, and since a compatible CMOS technique is used, manufacturing costs may be reduced and power consumption may be decreased.

Such a CMOS image sensor typically includes a pixel array region that captures an image. The pixel array region includes a photo diode that senses light. However, dark current flows in the photo diode due to various factors, such as heat energy, even when light is not sensed. Once such a dark current occurs, dark noise occurs in an image processing device, and due to this, its image quality is deteriorated.

### BRIEF SUMMARY

Embodiments of the subject invention provide an image sensor, and a method of manufacturing the same, that drastically reduces the thickness of dark shield necessary for forming a dark pixel region, while the dark pixel region for measuring dark current in the image sensor is formed.

In an embodiment, an image sensor can include a pixel array region including an active pixel area and a dark pixel area surrounding the active pixel area. The dark pixel area can include a dark shield to inhibit light and a dark pixel under the dark shield, and the dark shield can be a thin film including silicon chromium (SiCr).

In another embodiment, a method of manufacturing an image sensor can include forming a pixel array region by forming an active pixel area and a dark pixel area surrounding the active pixel area. Forming the dark pixel area can include forming a dark pixel and forming a dark shield over the dark pixel to inhibit light, and the dark shield can be a thin film including SiCr.

### BRIEF DESCRIPTION OF THE DRAWINGS

FIG. 1 is a view of a configuration of an image sensor according to an embodiment of the subject invention.

FIG. 2 is a circuit diagram of a unit pixel of the image sensor of FIG. 1.

FIG. 3 is a plan view when the unit pixel of FIG. 2 is integrated into a semiconductor substrate.

FIG. 4 is a plan view of a pixel array region of an image sensor according to an embodiment of the subject invention.

FIG. 5 is a diagram illustrating a process of calculating an actual optical signal from a signal delivered from a dark pixel region and an active pixel region.

FIG. 6 is a cross-sectional view of a configuration of an image sensor according to an embodiment of the subject invention.

FIG. 7 is a graph of reflectance versus wavelength for an embodiment of the subject invention and for a related art structure.

### DETAILED DESCRIPTION

Reference will now be made in detail to the embodiments of the present disclosure, examples of which are illustrated in the accompanying drawings.

When the terms “on” or “over” are used herein, when referring to layers, regions, patterns, or structures, it is understood that the layer, region, pattern, or structure can be directly on another layer or structure, or intervening layers, regions, patterns, or structures may also be present. When the terms “under” or “below” are used herein, when referring to layers, regions, patterns, or structures, it is understood that the layer, region, pattern, or structure can be directly under the other layer or structure, or intervening layers, regions, patterns, or structures may also be present.

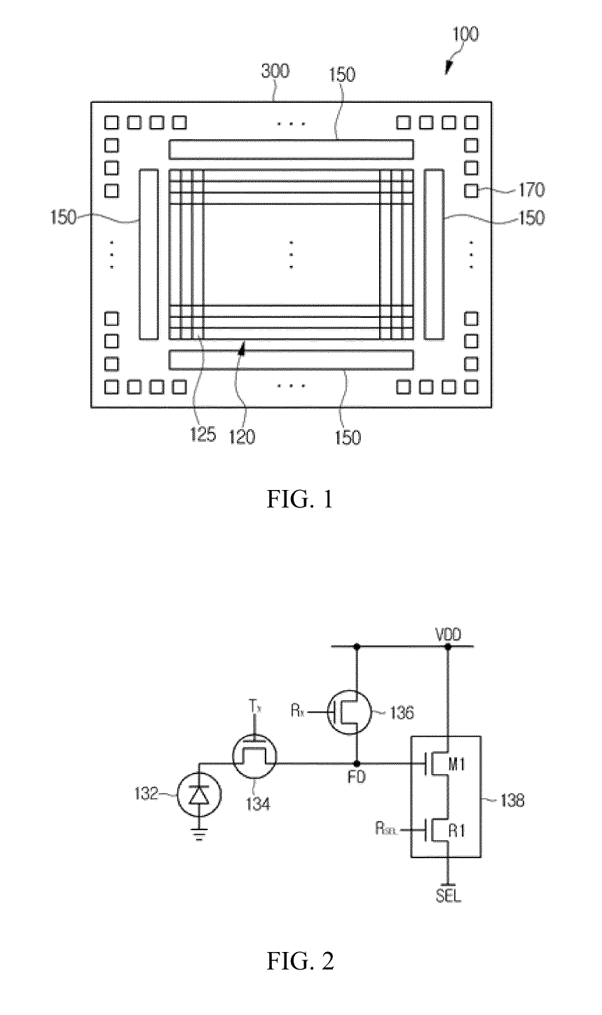

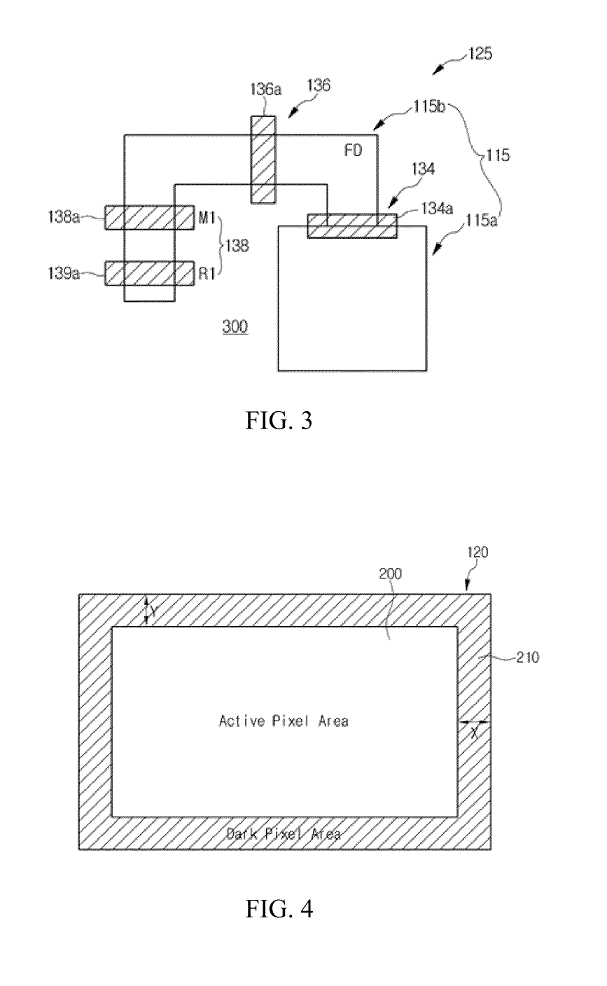

FIG. 1 is a view of a configuration of an image sensor according to an embodiment of the subject invention. FIG. 2 is a circuit diagram of a unit pixel of the image sensor of FIG. 1. FIG. 3 is a plan view when the unit pixel of FIG. 2 is integrated into a semiconductor substrate.

Referring to FIG. 1, in an embodiment, a complementary metal oxide semiconductor (CMOS) image sensor 100 can include a pixel array region 120, a CMOS logic region 150, and a pad 170 on a semiconductor substrate 300. The pixel array region 120 can include a plurality of unit pixels 125 in a matrix.

The CMOS logic regions 150 can be disposed at the edge surfaces of the pixel array region 120. The CMOS logic region 150 can include a plurality of CMOS transistors (not shown) and can provide a predetermined signal to each pixel of the pixel array region 120 or can control an output signal. The pad 170 can be used to exchange electrical signals with an external device.

Referring to FIG. 2, a unit pixel 125 can include a photo diode 132 for sensing light, a transfer transistor (Tx) 134 for delivering charges generated by the photo diode 132, a reset transistor (Rx) 136 for periodically resetting a floating diffusion region (FD) that stores the delivered charges, and a source follower 138 for buffering a signal according to the charges in the floating diffusion region FD.

The source follower 138 can include at least one metal oxide semiconductor (MOS) transistor. For example, the source follower 138 can include two MOS transistors M1 and R1 connected in series. One end of the reset transistor 136 and one end of the MOS transistor M1 can be connected to supply voltage VDD, and the gate electrode of the MOS transistor R1 can be connected to a row select signal line RSEL. One end of the MOS transistor R1 can be connected to a column select line SEL.

Referring to FIG. 3, the unit pixel 125 of the pixel array region 120 can be integrated into the semiconductor substrate 300. That is, an active region 115 can be formed on the semiconductor substrate 300. The active region 115 can include a photo diode region 115a and a transistor region 115b. The photo diode region 115a can be formed, for example, in a rectangular plate to occupy a predetermined portion of the semiconductor substrate 300 defined with a unit pixel region, though embodiments are not limited thereto.

The transistor region 115b can contact one side of the photo diode region 115a and can be formed, for example, in a line form bent at at least one portion, though embodiments are not limited thereto. The transistor region 115b can include a gate electrode 134a of a transfer transistor 134, a gate electrode 136a of a reset transistor 136, and gate electrodes 138a and 139a of a source follower 138.

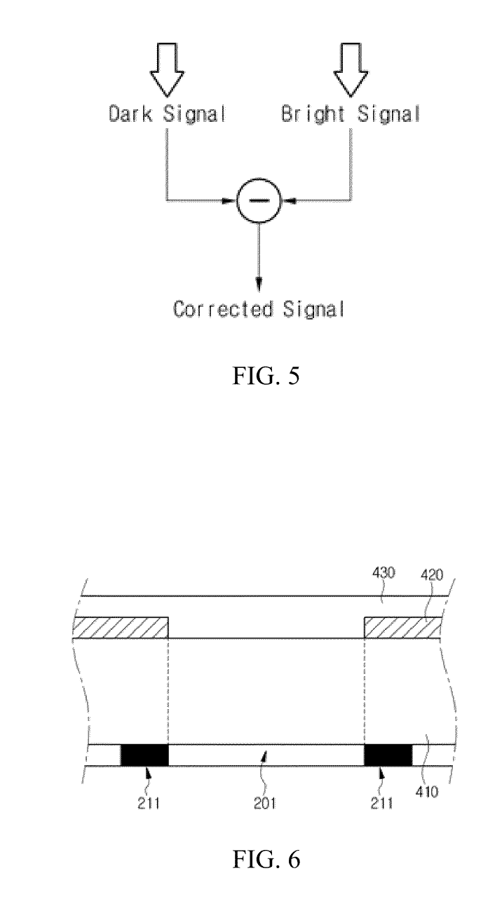

FIG. 4 is a plan view of a pixel array region of an image sensor according to an embodiment of the subject invention, and FIG. 5 is a diagram illustrating a process of calculating an actual optical signal from a signal delivered from a dark pixel region and an active pixel region.

Referring to FIG. 4, in an embodiment, the pixel array region 120 of the image sensor can include an active pixel area 200 and a dark pixel area 210 surrounding the active pixel area 200. The active pixel area 200 and the dark pixel area 210 can include a photo diode and a MOS transistor as described above.

The active pixel area 200 can be a portion sensing light when a CMOS image sensor is driven. The dark pixel area 210 can be used to examine and evaluate electrical characteristics of the active pixel area 200, that is, dark noise characteristics according to dark current (or leakage current) when light is blocked. For example, the dark pixel area 210 can examine and evaluate dark noise characteristics due to dark current, and based on this result, can compensate for a current value corresponding to a dark current of a photo diode in the active pixel area 200, in order to inhibit dark noise in an image processing device.

For example, Referring to FIG. 5, by subtracting a dark current value measured in the dark pixel area 210 from a total current value delivered to an image processing device, a current value can be calculated with respect to an actual light coming through the actual active pixel area 200.

Also, the horizontal size X and the vertical size Y of the dark pixel area 210 can be arbitrarily determined depending on process parameters.

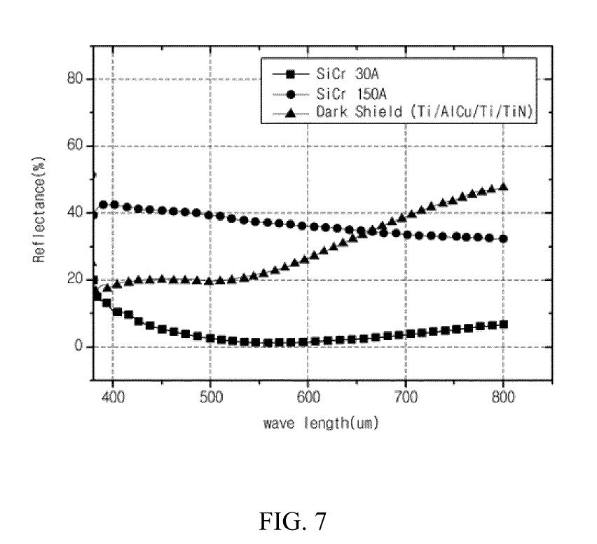

FIG. 6 is a cross-sectional view illustrating a configuration of an image sensor according to an embodiment of the present invention. FIG. 7 is a graph of reflectance (%) versus wavelength (μm). FIG. 7 compares a dark shield formed of silicon chromium (SiCr) according to an embodiment of the present invention with a related art structure.

Referring to FIG. 6, the image sensor can include: an active pixel area for obtaining image information by obtaining an electrical signal from received light; and a dark pixel area surrounding the active pixel area to obtain information on dark current of the image sensor.

The active pixel area can include an active pixel 201, and the pixel area can include a dark pixel 211. In an embodiment, the dark pixel 211 can also include a photo diode, but it is inhibited from receiving light by the dark shield 420 above it. Thus, this may be referred to as a dark pixel 211.

The active pixel 201 and the dark pixel 211 can each include a photo diode, but the active pixel 210 has a structure on which light is concentrated.

Additionally, when an active pixel area and a dark pixel area are formed, Back End Of Layers (BEOL) 410 can be formed thereon. The BEOL 410 can include, for example, at least one metallic layer, insulating layer, and/or metallic contact, though embodiments are not limited thereto. In addition, a dark shield 420 can be formed in the BEOL 410, and an insulating layer 430 can be formed on the BEOL 410. The insulating layer 430 can be formed of any suitable material known in the art, for example a nitride layer.

The dark shield 420 can be formed in the BEOL 410 in order to inhibit the dark pixel 211 from receiving light. In an embodiment the dark shield 420 can be formed of a material having high reflectivity in order to inhibit light from entering into the dark pixels 211.

In the related art, a plurality of insulating layers and metallic wires were formed in order to form the dark shield 420, and a dark shield manufactured in such a way may generally have a very thick thickness of about 2500 Å. For example, a dark shield having a multilayer structure including a Ti layer, an AlCu layer, a Ti layer, and a TiN layer may be used.

A dark current value obtained through a dark pixel is used to accurately calculate a current value including image information because a current value used as image information in an image processing device includes dark current in addition to a current value measured through an active pixel. However, in order to measure such a dark current value, if an excessive thickness of a related art dark shield is used, the thickness of an image sensor is increased.

Therefore, a dark shield according to embodiments of the present invention can be formed of SiCr, which has excellent light reflectivity characteristic and can be used for manufacturing a thin film.

The applicant suggested “a semiconductor device and a method of manufacturing the same” filed on Oct. 14, 2011, which discloses how to use the characteristics of electrical resistance that SiCr has by forming a thin film resistance layer with SiCr. SiCr can be used to form a thin film through a sputtering process and has excellent electrical conductivity so that it can be used as a resistance material of a thin film. Though, in an embodiment of the present invention, SiCr can be used as a material of a dark shield so as to form a dark pixel by using the low transmittance characteristic of SiCr.

When SiCr is used on a substrate, it can be used to form a thin film, so that the increased thickness, which may otherwise result from using one or more layers of a material having low optical transmittance, can be be inhibited. That is, a dark shield of a SiCr-based thin film can be formed, thereby reducing the thickness of an image sensor compared to that of the related art. According to embodiments of the present invention, a thick dark shield of a multilayered structure is not needed in order to more accurately calculate an active current by measuring dark current.

In embodiments of the subject invention, a thickness of an SiCr-based thin film can be any of the following values, about any of the following values, less than any of the following values, no more than any of the following values, or within any range having the following values as endpoints (all numerical values are in Å): 10, 20, 30, 40, 50, 60, 70, 80, 90, 100, 110, 120, 130, 140, 150, 160, 170, 180, 190, or 200. For example, a thickness of an SiCr-based thin film can be 30 Å, 150 Å, about 30 Å, about 150 Å, in a range of 30 Å to 150 Å, in a range of about 30 Å to about 150 Å, or no more than 150 Å.

FIG. 7 is a graph showing a reflectivity characteristic for a multilayered structure of Ti—AlCu—Ti—TiN according to a related art device. This is compared with a dark shield formed of a SiCr thin film according to an embodiment of the present invention. A dark shield according to an embodiment of the subject invention and having a thickness of about 30 Å is shown with the square points, and a dark shield according to an embodiment of the subject invention and having a thickness of about 150 Å is shown with the circular points. The related art device is shown with the triangular points.

When a dark shield is formed of SiCr and its thickness is about 30 Å or about 150 Å, the two thicknesses surprisingly have a similar reflectivity characteristic compared to a related art dark shield of a Ti—AlCu—Ti—TiN structure, even though they are much thinner.

That is, although a dark shield is not formed in a thick form according to a related art, if a thin film is formed of SiCr, high reflectivity that is exhibited in a related art dark shield can surprisingly be maintained.

Therefore, according to embodiments of the present invention, a dark shield can be formed of SiCr to inhibit light from entering into a dark pixel. As the thickness of the dark shield is drastically reduced compared to a related art, its reflectivity can surprisingly and advantageously be maintained.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

What is claimed is:

1. An image sensor, comprising:
a pixel array region comprising an active pixel area and a dark pixel area surrounding the active pixel area,
wherein the dark pixel area comprises a dark shield to inhibit light and a dark pixel under the dark shield, and
wherein the dark shield is a thin film comprising silicon chromium (SiCr).

2. The image sensor according to claim 1, wherein the thin film comprising SiCr has a thickness of about 30 Å to about 150 Å.

3. The image sensor according to claim 1, further comprising a Back End Of Layer (BEOL) in the dark pixel area, wherein the dark shield is disposed in the BEOL.

4. The image sensor according to claim 1, further comprising an insulating layer formed on the pixel array region, including on the dark shield.

5. The image sensor according to claim 1, wherein the active pixel area comprises a photo diode.

6. The image sensor according to claim 1, wherein the thin film comprising SiCr has a thickness of about 30 Å.

7. The image sensor according to claim 1, wherein the thin film comprising SiCr has a thickness of about 150 Å.

8. The image sensor according to claim 1, wherein the thin film comprising SiCr has a thickness of no more than 150 Å.

9. The image sensor according to claim 8, wherein the thin film of the dark shield consists of SiCr.

10. The image sensor according to claim 2, wherein the thin film of the dark shield consists of SiCr.

11. The image sensor according to claim 1, wherein the thin film of the dark shield consists of SiCr.

12. A method of manufacturing an image sensor, the method comprising:
forming a pixel array region by forming an active pixel area and a dark pixel area surrounding the active pixel area,
wherein forming the dark pixel area comprises forming a dark pixel and forming a dark shield over the dark pixel to inhibit light, and
wherein the dark shield is a thin film comprising silicon chromium (SiCr).

13. The method according to claim 12, wherein the thin film comprising SiCr has a thickness of about 30 Å to about 150 Å.

14. The method according to claim 12, further comprising forming a Back End Of Layer (BEOL) in the dark pixel area, wherein the dark shield is formed in the BEOL.

15. The method according to claim 12, further comprising forming an insulating layer on the pixel array region, including on the dark shield.

16. The method according to claim 12, wherein the thin film comprising SiCr has a thickness of about 30 Å.

17. The method according to claim 12, wherein the thin film comprising SiCr has a thickness of about 150 Å.

18. The method according to claim 12, wherein the thin film comprising SiCr has a thickness of no more than 150 Å.

19. The method according to claim 18, wherein the thin film of the dark shield consists of SiCr.

20. The method according to claim 12, wherein the thin film of the dark shield consists of SiCr.
